(19) United States
(12) Patent Application Publication
(10) Pub. No.: US 2026/0198323 A1
(43) Pub. Date: Jul. 9, 2026

(54) SEMICONDUCTOR PACKAGE

(71) Applicant: SAMSUNG ELECTRONICS CO., LTD., Suwon-si (KR)

(72) Inventors: Yoonyoung JEON, Suwon-si (KR); Jihye SHIN, Suwon-si (KR); Hyundong LEE, Suwon-si (KR); Ji-Hyun LIM, Suwon-si (KR)

(73) Assignee: SAMSUNG ELECTRONICS CO., LTD., Suwon-si (KR)

(21) Appl. No.: 19/278,066

(22) Filed: Jul. 23, 2025

(30) Foreign Application Priority Data
Jan. 7, 2025 (KR) 10-2025-0002068

(51) Int. Cl. H01L 23/00; H01L 23/31; H01L 23/498

(52) U.S. Cl. CPC H10W 42/121; H10W 70/685; H10W 74/141; H10W 90/701

(57) ABSTRACT

A semiconductor package includes a front redistribution structure, a semiconductor chip disposed above the front redistribution structure, a post disposed on the front redistribution structure and extending in a first direction substantially perpendicular to a surface of the front redistribution structure, a molding film disposed on the front redistribution structure, surrounding at least a portion of the semiconductor chip and at least a portion of the post, with at least a portion disposed between the semiconductor chip and the front redistribution structure, a barrier film disposed on the molding film and overlapping at least a portion of the molding film when viewed from the first direction, and a backside redistribution structure disposed on the molding film.

### CROSS-REFERENCE TO RELATED APPLICATIONS

This application claims priority under 35 USC § 119 to the benefit of Korean Patent Application No. 10-2025-0002068, filed on Jan. 7, 2025, in the Korean Intellectual Property Office, the disclosure of which is incorporated herein by reference in its entirety.

### BACKGROUND

### 1. Field of the Invention

Example embodiments relate to a semiconductor package.

### 2. Description of the Related Art

With rapid development in the electronics industry and the growing demands of users, electronic devices are becoming more compact, high-capacity, and multifunctional. To provide such functions, a semiconductor package is developed, in which a semiconductor chip with an integrated circuit is protected through a molding film for example, and the redistribution layer (RDL) is electrically connected to the semiconductor chip via posts, thereby addressing the limitations in developing technologies for refining circuit line widths.

During a process of manufacturing semiconductor packages, there may be cases of a rework, which require removal of the insulating film that forms the redistribution layer. To remove the insulating film, a strip solution may be used and a cleaning solution may also be used to clean the strip solution. The strip solution and cleaning solution may be absorbed by the molding film and cause the molding film to swell. The swollen molding film may affect product reliability. Also, the strip solution eluted from the swollen molding film may oxidize a portion of the posts and it may cause poor electrical connection.

### SUMMARY

An aspect provides a semiconductor package capable of ensuring product reliability by minimizing swelling of a molding film and minimizing risks of weakened electrical connection caused by oxidization of a post.

However, the goals to be achieved by example embodiments of the present disclosure are not limited to the objectives described above and other objects may be clearly understood from the following example embodiments by those skilled in the art.

According to an aspect, there is provided a semiconductor package including a front redistribution structure, a semiconductor chip disposed above the front redistribution structure, a post disposed on the front redistribution structure and extending in a first direction which is a direction substantially perpendicular to a surface of the front redistribution structure, a molding film disposed on the front redistribution structure, surrounding at least a portion of the semiconductor chip and at least a portion of the post, with at least a portion disposed between the semiconductor chip and the front redistribution structure, a barrier film disposed on the molding film and overlapping at least a portion of the molding film when viewed from the first direction, and a backside redistribution structure disposed on the molding film.

According to another aspect, there is also provided a semiconductor package including a front redistribution structure, a semiconductor chip disposed above the front redistribution structure, a post disposed on the front redistribution structure and extending in a first direction which is a direction substantially perpendicular to a surface of the front redistribution structure, a molding film disposed on the front redistribution structure, surrounding at least a portion of the semiconductor chip and at least a portion of the post, with at least a portion disposed between the semiconductor chip and the front redistribution structure, a barrier film disposed on the molding film and surrounding the post when viewed from the first direction, and a backside redistribution structure disposed on the molding film.

According to still another aspect, there is provided a semiconductor package including a front redistribution structure, a semiconductor chip disposed above the front redistribution structure, a post disposed on the front redistribution structure and extending in a first direction which is a direction substantially perpendicular to a surface of the front redistribution structure, a molding film disposed on the front redistribution structure, surrounding at least a portion of the semiconductor chip and at least a portion of the post, with at least a portion disposed between the semiconductor chip and the front redistribution structure, a barrier film which is disposed on the molding film and, when viewed from the first direction, overlapping at least a portion of the molding film, surrounding the post, and not overlapping the post, and a backside redistribution structure disposed on the molding film, wherein the barrier film includes a first barrier film disposed on the molding film and a second barrier film disposed on the first barrier film and further away from the front redistribution structure than the first barrier film, a ratio (T₁/T₂) of a thickness of the first barrier film (T₁) and a thickness of the second barrier film (T₂) is greater than or equal to 0.1 and less than 1, and a portion of the molding film is further disposed between the semiconductor chip and the barrier film.

According to still another aspect, there is provided a method of manufacturing a semiconductor package including forming a front redistribution structure on a carrier, mounting a semiconductor chip in the front redistribution structure and forming a post, forming a molding film to surround the semiconductor chip and the post, removing a portion of the molding film to expose the post, forming a barrier film on the exposed post, removing a portion of the barrier film to re-expose the post, and forming a backside redistribution structure on the molding film to be electrically connected to the re-exposed post.

Detailed descriptions of other example embodiments are included in the detailed description and drawings.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is an example drawing of a semiconductor package according to an example embodiment of the present disclosure;

FIG. 2 is an example drawing of a semiconductor package according to an example embodiment of the present disclosure;

FIG. 3 is a top plan view of a semiconductor package according to an example embodiment of the present disclosure;

FIG. 4 is an example drawing of a semiconductor package according to an example embodiment of the present disclosure;

FIG. 5 is an enlarged view of section P of FIG. 4;

FIG. 6 is an example drawing of a semiconductor package according to an example embodiment of the present disclosure;

FIG. 7 is a top plan view of a semiconductor package according to an example embodiment of the present disclosure; and

FIGS. 8 through 32 are example drawings for describing a method of manufacturing a semiconductor package according to an example embodiment of the present disclosure.

### DETAILED DESCRIPTION

A physical property described in the present disclosure may be measured at normal temperature and pressure unless specifically limited. The normal temperature in the present disclosure may be non-manipulated natural temperature within a range from 10 degrees Celsius (C) to 30° C., from 20° C. to 28° C., or from 22° C. to 26° C. In an example embodiment, the normal temperature may be 25° C. The normal pressure in the present disclosure may be non-manipulated natural pressure within a range from 700 millimeters of mercury (mmHg) to 800 mmHg or from 720 mmHg to 780 mmHg. In an example embodiment, the normal pressure may be 760 mmHG.

Physical properties described in the present disclosure may use units complying with the international system of units (SI) unless otherwise specified.

Hereinafter, example embodiments according to the technical spirit of the present disclosure will be described with reference to the drawings. In addition, existing elements, structures, or layers of the semiconductor package according to an example embodiment may or may not be described in detail for brevity. For example, a description of separation structures or other structures included in the semiconductor package and materials forming the structures may be omitted if they are not closely related to the novel features of example embodiments.

The drawings illustrated in the present disclosure are according to mere example embodiments, and the ratio of the width, the length and the height (or the thickness) of each element is for detailed descriptions for the example embodiments, and thus the ratio may differ from reality. Further, in the coordinate system illustrated in the drawings, each axis may be perpendicular to each other, and the direction the arrow points may be the + direction, and the direction opposite to the direction indicated by the arrow (rotated by 180 degrees) may be the − direction.

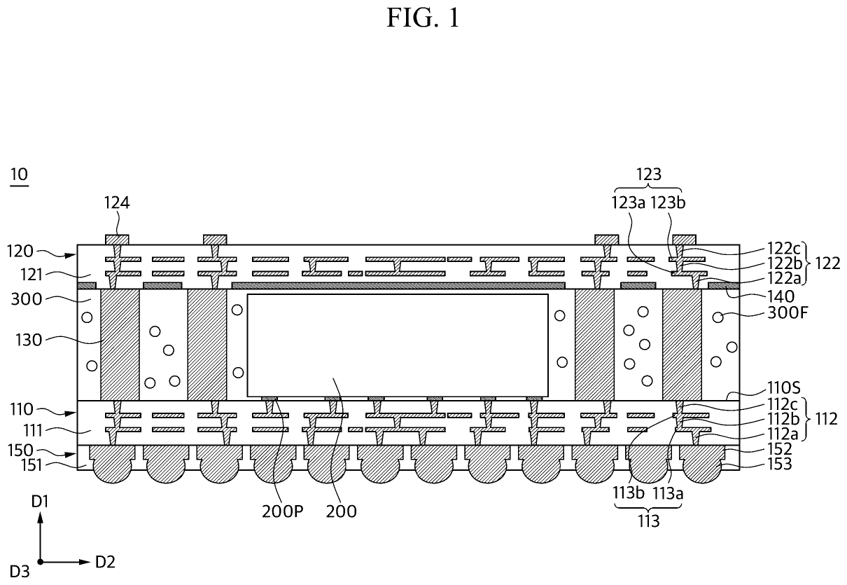

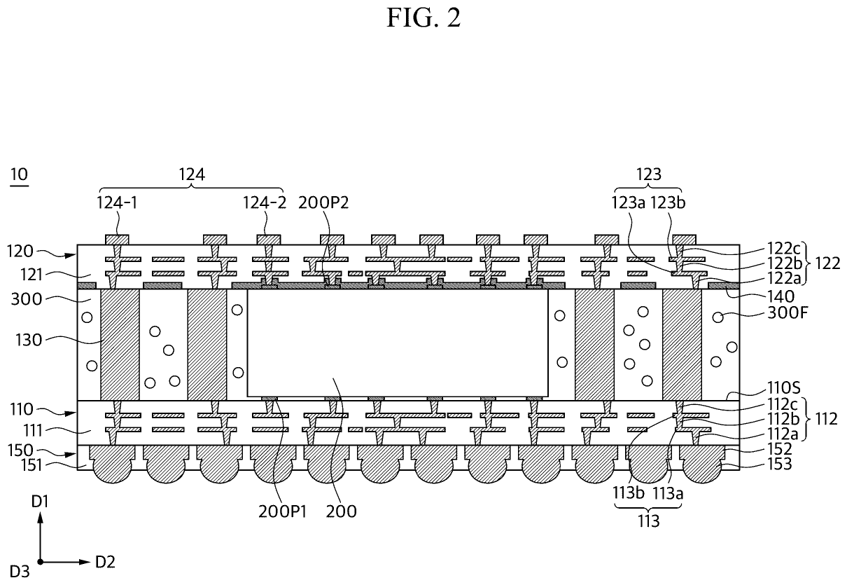

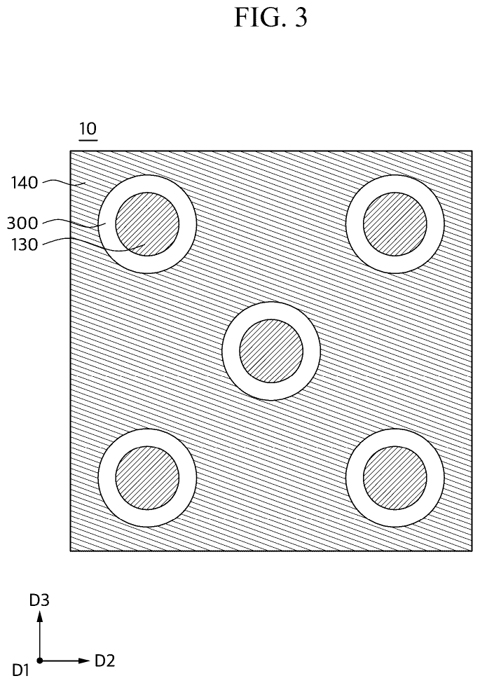

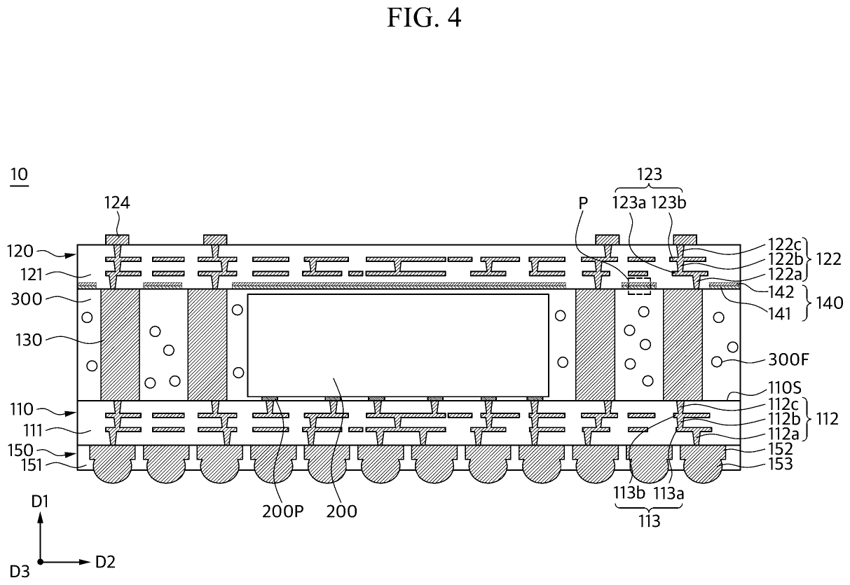

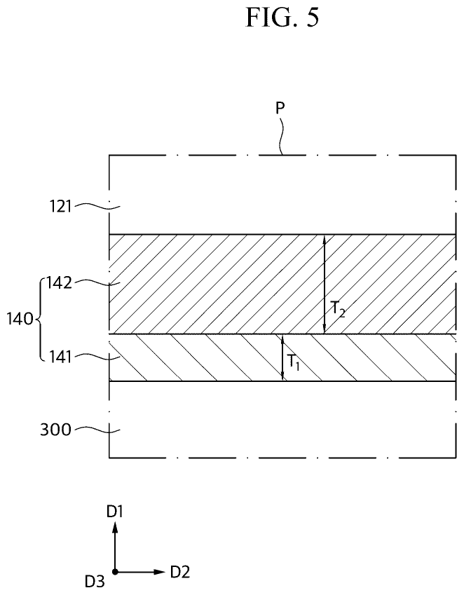

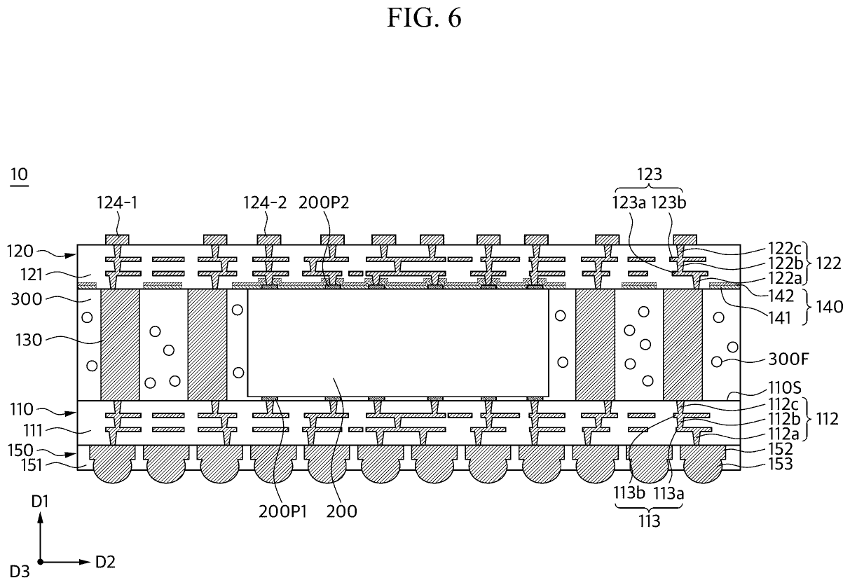

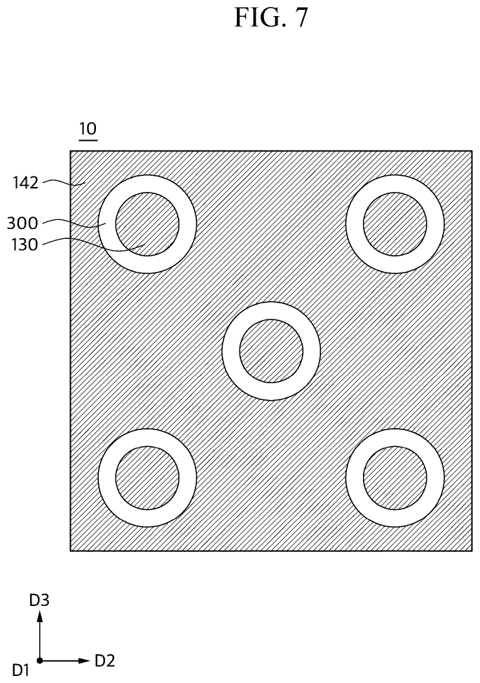

FIG. 1 is an example drawing of a semiconductor package 10 according to an example embodiment of the present disclosure. FIG. 2 is an example drawing of the semiconductor package 10 according to an example embodiment of the present disclosure. FIG. 3 is a top plan view of the semiconductor package 10 without a backside redistribution structure according to an example embodiment of the present disclosure. FIG. 4 is an example drawing of the semiconductor package 10 according to an example embodiment of the present disclosure. FIG. 5 is an enlarged view of section P of FIG. 4. FIG. 6 is an example drawing of the semiconductor package 10 according to an example embodiment of the present disclosure. FIG. 7 is a top plan view of the semiconductor package 10 without a backside redistribution structure according to an example embodiment of the present disclosure.

In the present specification, an insulating material may have an electrical conductivity of 10⁻⁶ S/m or lower. Electrical conductivity in the present specification may be measured based on ASTM E 1004, although not specifically limited thereto. For example, the insulating material may include one or more materials selected from a group including silicon oxide, silicon-germanium oxide, germanium oxide, silicon oxynitride, silicon nitride, a high dielectric material with higher dielectric constant than silicon nitride, and a low dielectric material with lower dielectric constant than silicon nitride. The high dielectric material, for example, may include one or more materials from a group including boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but this is merely an example. The low dielectric material may include one or more materials from a group including fluorinated tetraethyl orthosilicate (FTEOS), hydrogen silsesquioxane (HSQ), bis-benzocyclobutene (BCB), tetramethyl orthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilyl phosphate (TMSP), polytetrafluoroethylene (PTFE), tonen silazene (TOSZ), fluoride silicate glass (FSG), polyimide nanofoams such as polypropylene oxide, carbon doped silicon oxide (CDO), organo silicate glass (OSG), silicon lithium potassium (SiLK), amorphous fluorinated carbon, silica aerogels, silica xerogels, and mesoporous silica, but this is merely an example.

In the present specification, a conductive material may have an electrical conductivity greater than or equal to 106 S/m. For example, the conductive material may include at least one of metal, metal alloy, conductive metal nitride, metal silicide, a doped semiconductor material, conductive metal oxide, and conductive metal oxynitride. For example, the conductive material may include one or more selected from a group consisting titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAIC-N), titanium aluminum carbide (TiAIC), titanium carbide (TiC), tantalum carbonitride (TaCN) tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (NoC), tungsten carbide (WC), rhodium (Rh), palladium (Pd), iridium (Ir), osmium (Os), silver (Ag), gold (Au), zinc (Zn), and vanadium (V), but this is merely an example. The conductive metal oxide and the conductive metal oxynitride may include an oxidized form of the described material, but this is merely an example.

In the present disclosure, a first direction D1 may refer to a direction substantially perpendicular to a front surface 110S of a front redistribution structure. A second direction D2 may refer to a direction substantially parallel to the front surface 110S of the front redistribution structure. The second direction D2 may cross the first direction D1. For example, the second direction D2 may be substantially perpendicular to the first direction D1. A third direction D3 may refer to a direction substantially parallel to the front surface 110S of the front redistribution structure while crossing the first direction D2. The third direction D3 may cross the first direction D1. For example, the third direction D3 may be substantially perpendicular to the first direction D1. Also, for example, the third direction D3 may be substantially perpendicular to the second direction D2.

One or ordinary skill in the art would understand that the expression “substantially perpendicular” or “substantially parallel” may mean not only being exactly perpendicular (90°) or exactly parallel (0°) but also being close to perpendicular or close to parallel including process errors, positional deviations, and/or measurement errors that may occur in a manufacturing process, and the range thereof may be widely accepted in the art. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

According to an example embodiment, the semiconductor package 10 may include a package-on-package structure. According to an example embodiment, the semiconductor package 10 may include a fan-in wafer-level package (FIWLP) structure or a fan-out wafer-level package (FOWLP) structure. Without being limited to those illustrated in the drawings, the semiconductor package 10 may also include other well-known package structures.

According to an example embodiment, the semiconductor package 10 may include a front redistribution structure 110, a backside redistribution structure 120, a post 130, a barrier film 140, a semiconductor chip 200, and a molding film 300.

According to an example embodiment, the front redistribution structure 110 and the backside redistribution structure 120 may each be at least a portion of a package substrate. The front redistribution structure 110 may be an interconnection structure for a package. The front redistribution structure 110 may be an interconnection structure for a wafer-level package (WLP) which is formed at a wafer level.

According to an example embodiment, the front redistribution structure 110 may include a first insulating film 111. The first insulating film 111 may include an insulating material. The first insulating film 111 may have a single-layer structure or multi-layer structure.

According to an example embodiment, the front redistribution structure 110 may include a first interconnection structure which is disposed within the first insulating film 111. The first interconnection structure may include a front redistribution via 112 and a front redistribution line 113 which is electrically connected to the front redistribution via 112. The front redistribution via 112 and the front redistribution line 113 may include conductive materials. The front redistribution via 112 may pass through at least a portion of the first insulating film 111 in the first direction D1. The front redistribution line 113 may extend in a direction crossing the front redistribution via 112 (e.g., the second direction D2). The front redistribution via 112 and the front redistribution line 113 may have a patterned structure.

According to an example embodiment, the front redistribution structure 110 may include a plurality of front redistribution vias 112. For example, the front redistribution structure 110 may include a first front redistribution via 112a, a second front redistribution via 112b, and a third front redistribution via 112c. When viewed from the second direction D2, the first front redistribution via 112a, the second front redistribution via 112b, and the third redistribution via 112c each may not be overlapped.

According to an example embodiment, the front redistribution structure 110 may include a plurality of front redistribution lines 113. For example, the front redistribution line 113 may include a first front redistribution line 113a and a second front redistribution line 113b. The first front redistribution line 113a may be disposed between the first front redistribution via 112a and the second front redistribution via 112b, and may electrically connect the first front redistribution via 112a and the second front redistribution via 112b. The second front redistribution line 113b may be disposed between the second front redistribution via 112b and the third front redistribution via 112c, and may electrically connect the second front redistribution via 112b and the third front redistribution via 112c.

According to an example embodiment, the semiconductor package 10 may include an external connection structure 150 which is electrically connected to the front redistribution structure 110. The external connection structure 150 may include an external connection insulating film 151. The external connection insulating film 151 may include an insulating material. The external connection insulating film 151 may have a single-layer structure or multi-layer structure.

According to an example embodiment, the external connection structure 150 may be disposed within the external connection insulating film 151, and may include an external connection pad 152 which is electrically connected to the first interconnection structure. More than one external connection pad 152 may be provided, and a plurality of external connection pads 152 may be disposed to be spaced apart from each other in the second direction D2. The number, space, arrangement, and shape of the external connection pads 152 are not limited to those illustrated in the drawings and may vary according to the design.

According to an example embodiment, the external connection structure 150 may include an external connection member 153 to be electrically connected to another package or chip. Through the external connection member 153, an electrical signal (e.g., power signal, ground signal, or input/output signal, etc.) may be received from an outside source, or transmitted outside. The external connection member 153 may be disposed to be protruded from the external connection insulating film 151 in a negative first direction −D1, or have a part of its surface exposed in the negative first direction −D1 while disposed within the external connection member 153. The external connection member 153 may include a conductive material. For example, the external connection member 153 may include at least one selected from a group including tin (Sn), indium (In), bismuth (Bi), antimony (Sb), copper (Cu), silver (Ag), zinc (Zn), and lead (Pb). The external connection member 153 may have a ball shape (e.g., solder ball) or a bump shape (e.g., solder bump), however this is merely an example, and the external connection member 153 may have a pad shape. The number, space, arrangement, and shape of the external connection members 153 are not limited to those illustrated in the drawings, and may vary according to the design. For example, the number, space, arrangement, shape, and the like of the external connection members 153 may be provided to correspond to the number, space, arrangement, shape, and the like of the external connection pads 152.

According to an example embodiment, the backside redistribution structure 120 may be disposed to be spaced apart from the front redistribution structure 110 in the first direction D1. The backside redistribution structure 120 may be disposed on the molding film 300. The molding film 300 may be disposed between the front redistribution structure 110 and the backside redistribution structure 120.

According to an example embodiment, the backside redistribution structure 120 may include the second insulating film 121. The second insulating film 121 may include an insulating material. The second insulating film 121 may have a single-layer structure or multi-layer structure.

According to an example embodiment, the backside redistribution structure 120 may include a second interconnection structure which is disposed within the second insulating film 121. The second interconnection structure may include a backside redistribution via 122, and a backside redistribution line 123 which is electrically connected to the backside redistribution via 122. The backside redistribution via 122 and the backside redistribution line 123 may include conductive materials. The backside redistribution via 122 may pass through at least a portion of the second insulating layer 121 in the first direction D1. The backside redistribution line 123 may extend in a direction crossing the backside redistribution via 122 (e.g., the second direction D2). The backside redistribution via 122 and the backside redistribution line 123 may have a patterned structure.

According to an example embodiment, the backside redistribution structure 120 may include a plurality of backside redistribution vias 122. For example, the backside redistribution structure 120 may include a first backside redistribution via 122a, a second backside redistribution via 112b, and a third backside redistribution via 122c. When viewed from the second direction D2, each of the first backside redistribution via 122a, the second backside redistribution via 122b, and the third backside redistribution via 122c may not be overlapped.

According to an example embodiment, the backside redistribution structure 120 may include a plurality of backside redistribution lines 123. For example, the backside redistribution line 123 may include a first backside redistribution line 123a and a second backside redistribution line 123b. The first backside redistribution line 123a may be disposed between the first backside redistribution via 122a and the second backside redistribution via 122b and electrically connect the first backside redistribution via 122a and the second backside redistribution via 122b. The second backside redistribution line 123b may be disposed between the second backside redistribution via 122b and the third backside redistribution via 122c and electrically connect the second backside redistribution via 122b and the third backside redistribution via 122c.

According to an example embodiment, the backside redistribution structure 120 may include a connection member 124 to electrically connect the semiconductor package 10 with another package or chip. The connection member 124 may be disposed to be protruded from the second insulating film 121 in a positive first direction +D1, or a portion of its surface may be exposed in the positive first direction +D1 while disposed within the second insulating film 121. The connection member 124 may include a conductive material. For example, the connection member 124 may include at least one selected from a group including tin (Sn), indium (In), bismuth (Bi), antimony (Sb), copper (Cu), silver (Ag), zinc (Zn), and lead (Pb). The connection member 124 may have a pad shape, but this is merely an example and the connection member 124 may have a ball shape or bump shape. The number, space, arrangement, and shape of the connection members 124 are not limited to those illustrated in the drawings and may vary according to the design. When viewed from the first direction D1, at least a portion of the connection member 124 may overlap the post 130. More than one connection member 124 may be provided, and a plurality of connection members 124 may be disposed to be spaced apart from each other in the second direction D2.

According to an example embodiment, the post 130 may be electrically connected to each of the front redistribution structure 110 and the backside redistribution structure 120. The post 130 may include a conductive material. For example, the post 130 may include copper (Cu).

According to an example embodiment, the post 130 may be disposed on the front redistribution structure 110. The post 130 may extend in the first direction D1. The post 130 may pass through the molding film 300 in the first direction D1. The post 130 may extend to have an equal height as the semiconductor chip 200 (refer to FIG. 2 or 6) in the first direction D1, or may extend to have a height greater than that of the semiconductor chip 200 (refer to FIGS. 1 and 4). The height of the semiconductor chip 200 may refer to a length of the semiconductor chip 200 in the first direction D1. Here, being extended to be equal means being substantially equal, and may refer to a case in which a ratio of the difference between the extended length of the post 130 in the first direction D1 and the height of the semiconductor chip 200 compared to the extended length of the post 130 in the first direction D1 is less than or equal to 5%.

According to an example embodiment, more than one post 130 may be provided. A plurality of posts 130 may be spaced apart from each other in the second direction D2. Also, the post 130 may be disposed to be spaced apart from the semiconductor chip 200 in the second direction D2.

According to an example embodiment, the barrier film 140 may be disposed on the molding film 300 to overlap at least a portion of the molding film 300 when viewed from the first direction D1. The barrier film 140, by being disposed to overlap at least a portion of the molding film 300, may ensure product reliability by minimizing swelling of the molding film 300 and minimizing risks of weakened electrical connection caused by oxidization of the post 130.

According to example embodiments, it is possible to provide a semiconductor package which is capable of ensuring product reliability by minimizing swelling of a molding film and minimizing risks of weakened electrical connection caused by oxidization of a post.

Effects of the present disclosure are not limited to those described above and other effects may be made apparent to those skilled in the art from the following description.

According to an example embodiment, the barrier film 140 may include a conductive material. For example, the barrier film 140 may include metal. Through this, the barrier film 140 may ensure product reliability by minimizing risks that may be caused by the strip solution and cleaning solution for cleaning the strip solution, even when the barrier film 140 is included.

According to an example embodiment, the barrier film 140 may include a multi-layer structure. For example, referring to FIGS. 2 and 4, the barrier film 140 may include a first barrier film 141 which is disposed adjacent to the front redistribution structure 110, and a second barrier film 142 which is disposed on the first barrier film 141. For example, the first barrier film 141 may be disposed on the molding film 300. For example, the first barrier film 141 may be disposed on the molding film 300 and the post 130. For example, the second barrier film 142 may be disposed farther from the front redistribution structure 110 than the first barrier film 141.

According to an example embodiment, a thickness T₁ of the first barrier film 141 may be smaller than a thickness T₂ of the second barrier film 142. A ratio (T₁/T₂) of the thickness T₁ of the first barrier film 141 and the thickness T₂ of the second barrier film 142 may be greater than or equal to 0.1 and less than 1, greater than or equal to 0.15 and less than or equal to 0.9, greater than or equal to 0.2 and less than or equal to 0.8, or greater than or equal to 0.25 and less than or equal to 0.75.

As one exemplary measurement method of the aforementioned widths, a “thickness” of a component between two targeted surfaces of the component may mean an average value of shortest distances between the two targeted surfaces measured in a direction perpendicular to the targeted surfaces at multiple locations (e.g., 3, 5, or 10) at equal intervals (or non-equal intervals, alternatively). Other methods appreciated by one of ordinary skill in the art, even if not described in the present disclosure, may also be used.

According to an example embodiment, the first barrier film 141 may include a metal with higher peel strength with respect to the molding film 300 than that of the second barrier film 142. The peel strength, for example, may refer to peeling strength when the molding film 300 is being peeled off from a metal layer after forming a flat metal layer on a flat molding film 300. For example, the first barrier film 141 may include titanium (Ti). The second barrier film 142 may include at least one selected from a group including copper (Cu), gold (Au), silver (Ag), and nickel (Ni).

According to an example embodiment, the post 130 and the second barrier film 142 may include the same materials. For example, the post 130 and the second barrier film 142 may include the same metal. The post 130 and the second barrier film 142 may include copper (Cu).

In one example, the barrier film 140 may not overlap the post 130 when viewed from the first direction D1. Through this, an electrical signal traveling through the post 130 may be prevented from being leaked to the barrier film 140.

Referring to FIG. 3, the barrier film 140 may surround the post 130 when viewed from the first direction D1. The molding film 300 may be disposed between the barrier film 140 and the post 130. When viewed from the first direction D1, a distance between the barrier film 140 and the post 130 may vary based on the type of an insulating material included in the second insulating film 121.

Referring to FIG. 7, the second barrier film 142 may surround the post 130 when viewed from the first direction D1. The molding film 300 may be disposed between the second barrier film 142 and the post 130.

According to an example embodiment, the semiconductor chip 200 may be disposed on the front redistribution structure 110. At least a portion of the semiconductor chip 200 may be disposed in the molding film 300. In other words, the molding film 300 may surround at least a portion of the semiconductor chip 200.

Referring to FIGS. 1 and 4, the semiconductor chip 200 may include a chip pad 200P which is electrically connected to the front redistribution structure 110. The chip pad 200P may include a conductive material. The chip pad 200P may include metal. The chip pad 200P may include at least one selected from a group including copper (Cu) titanium (Ti), gold (Au), silver (Ag), and nickel (Ni). At least one chip pad 200P may be electrically connected to the first interconnection structure.

According to an example embodiment, the molding film 300 may be disposed on the front redistribution structure 110. The molding film 300 may include a resin material or a filler 300F dispersed in a resin material. The resin material may include, for example, an epoxy molding compound (EMC). The filler 300F may include silica.

According to an example embodiment, the molding film 300 may surround at least a portion of the semiconductor chip 200. The molding film 300 may surround at least a portion of the post 130. A portion of the molding film 300 may be disposed between the semiconductor chip 200 and the front redistribution structure 110.

According to an example embodiment, the second insulating film 121 may be in contact with the post 130, barrier film 140, and molding film 300. Through this, product reliability may be ensured by minimizing swelling of the molding film 300 and minimizing risks of weakened electrical connection caused by oxidization of the post 130.

Referring to FIGS. 1 and 4, a portion of the molding film 300 may be disposed between the semiconductor chip 200 and the barrier film 140. A portion of the chip pad 200P may be disposed within the molding film 300, and a portion of its surface may be exposed in a direction toward the front redistribution structure 110 (that is, the negative first direction −D1).

Referring to FIGS. 2 and 6, the semiconductor chip 200 may include a first chip pad 200P1 which is electrically connected to the front redistribution structure 110 and a second chip pad 200P2 which is electrically connected to the backside redistribution structure 120. With regard to the backside redistribution structure 120, the connection member 124 may include a first connection member 124-1 which is electrically connected to the post 130, and a second connection member 142-2 which is electrically connected to the second chip pad 200P2. A portion of the first chip pad 200P1 may be disposed within the molding film 300, and a portion of its surface may be exposed in a direction towards the front redistribution structure 110 (that is, the negative first direction −D1). The second chip pad 200P2 may be disposed to be protruded from the semiconductor chip 200 in the positive first direction +D1. As a result, the barrier film 140 may be disposed to surround the protruded area of the second chip pad 200P2.

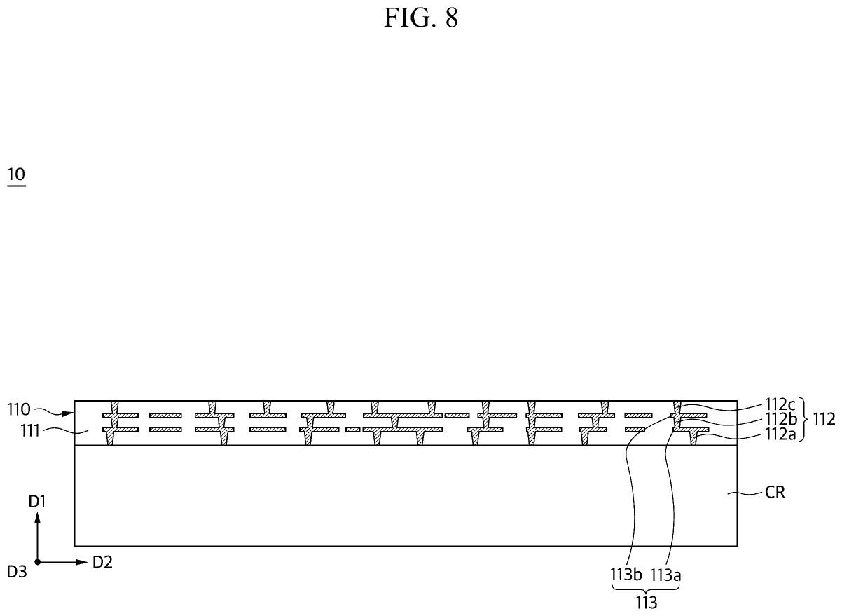

FIGS. 8 through 32 are example drawings for describing a method of manufacturing the semiconductor package 10 according to an example embodiment of the present disclosure. FIGS. 8 through 20 are example drawings for describing a method of manufacturing the semiconductor package 10 according to FIGS. 1 through 3. According to an example embodiment, a well-known method may be applied as the method of manufacturing the semiconductor package 10 unless otherwise contradicted. Hereinafter, a method of securing structural features of the above-described semiconductor package 10 will be described primarily.

A predetermined film or a layer, although is not specifically limited in the present specification, may be, in one example, formed through deposition, and the deposition performed may be, for example, chemical vapor deposition (CVD), physics vapor deposition (PVD), or atomic layer deposition (ALD). When a method other than deposition of a predetermined film or layer used in the art is present, the method may be applied. In addition, although the predetermined film or layer are not particularly limited in the present specification, in one example, the predetermined film or the layer may be removed through etching, and the etching performed may be wet etching which uses phosphoric acid and the like, dry etching, or the like.

Referring to FIG. 8, the method of manufacturing the semiconductor package 10 may include forming the front redistribution structure 110 on a carrier CR. The carrier CR, for example, may include a silicon material such as glass or silicon oxide, an organic material, aluminum oxide, and the like.

According to an example embodiment, the method of manufacturing the semiconductor package 10 may include forming the first insulating film 111 on the carrier CR. The method of manufacturing the semiconductor package 10 may include forming via holes by selectively etching the first insulating film 111 and filling the via holes with a conductive material. By filling the via holes with a conductive material, the first interconnection structure including the front redistribution via 112 and the front redistribution line 113 may be formed. For example, the method of manufacturing the semiconductor package 10 may include forming a first region which is a portion of the first insulating film 111, forming via holes by selectively etching them, and forming the front redistribution via 112 by filling the via holes with a conductive material. The method of manufacturing the semiconductor package 10 may include forming a second region, which is a portion of the first insulating film 111, in the first region in which the front redistribution via 112 is formed, forming via holes by selectively etching them, and forming the front redistribution line 113 by filling the via holes with a conductive material. By repeating the process, the front redistribution via 112 including the first front redistribution via 112a, the second front redistribution via 112b, and the third front redistribution via 112c may be formed, and the front redistribution line 113 including the first front redistribution line 113a and the second front redistribution line 113b may be formed. The front redistribution via 112 and the front redistribution line 113 may be formed, for example, by sputtering.

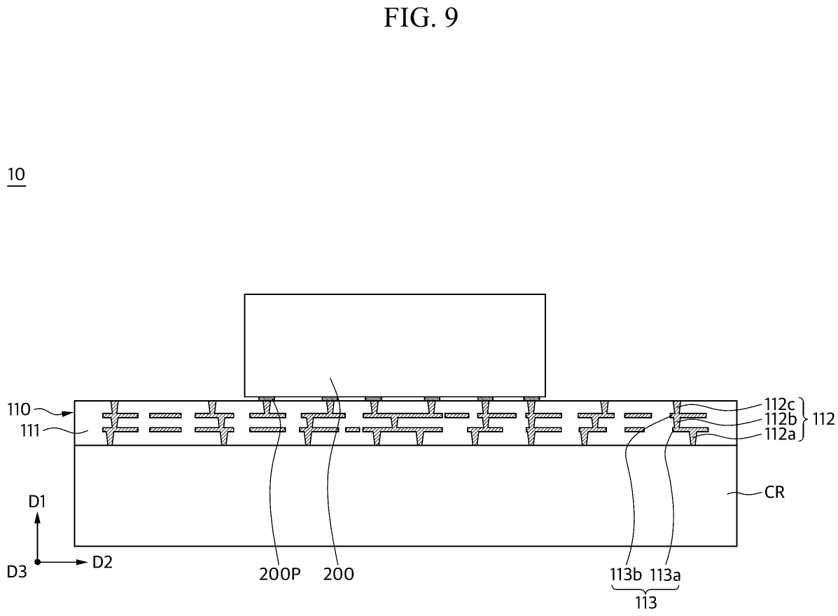

Referring to FIG. 9, the method of manufacturing the semiconductor package 10 may include mounting the semiconductor chip 200 on the front redistribution structure 110. For example, the semiconductor chip 200 and the front redistribution structure 110 may be electrically connected to each other as the chip pad 200P of the semiconductor chip 200 is bonded to the front redistribution via 112 or the front redistribution line 113.

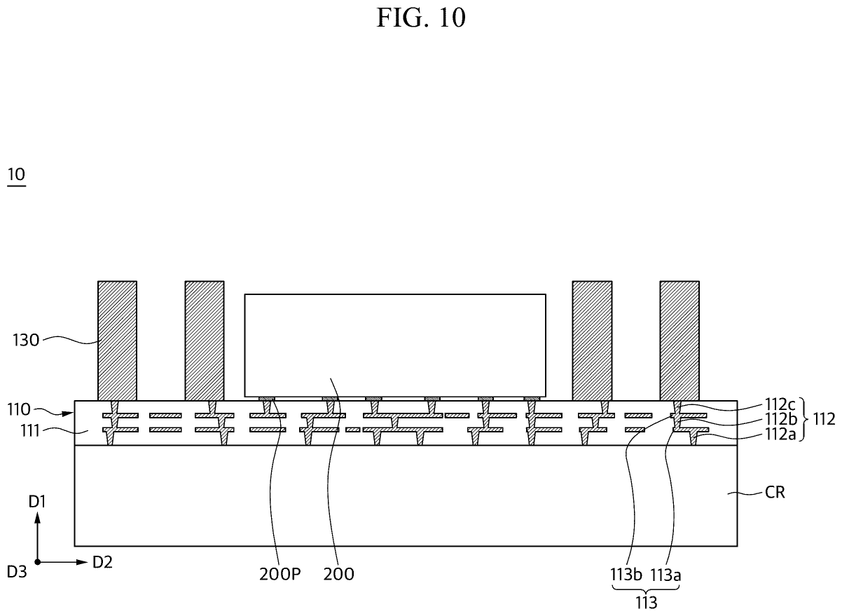

Referring to FIG. 10, the method of manufacturing the semiconductor package 10 may include forming the post 130 on the front redistribution structure 110. The post 130 may be bonded onto the front redistribution structure 110 and formed to extend in the first direction D1. For example, the post 130 may be formed through sputtering.

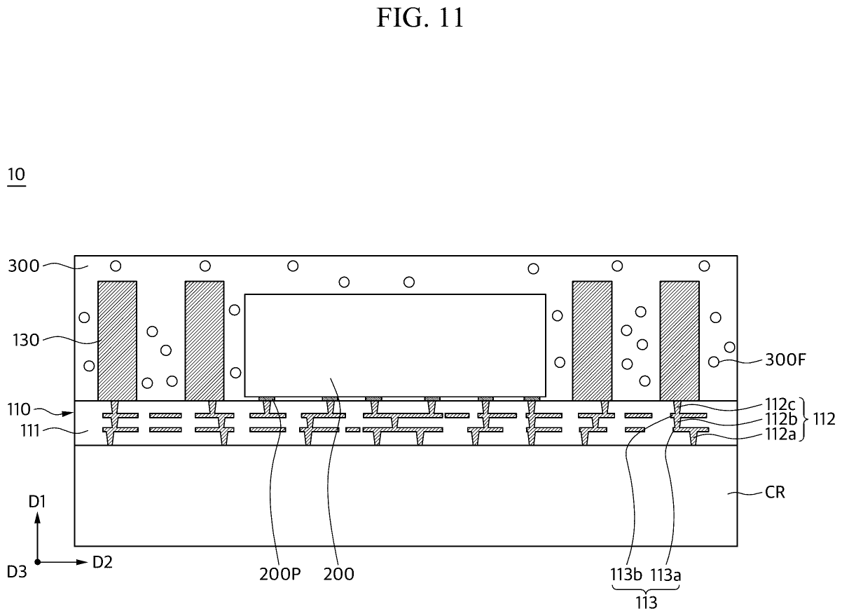

Referring to FIG. 11, the method of manufacturing the semiconductor package 10 may include forming the molding film 300 to surround the semiconductor chip 200 and the post 130. The molding film 300, for example, may be formed through press molding or transfer molding.

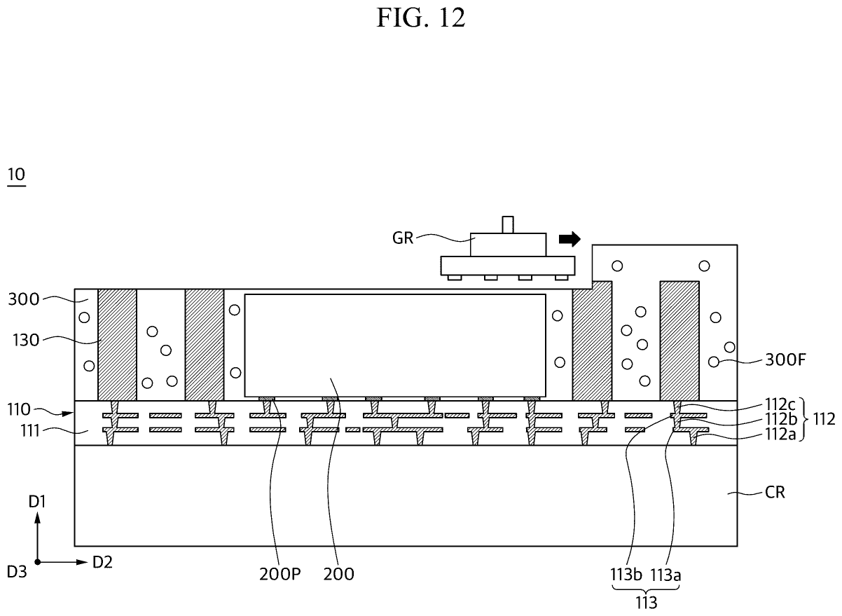

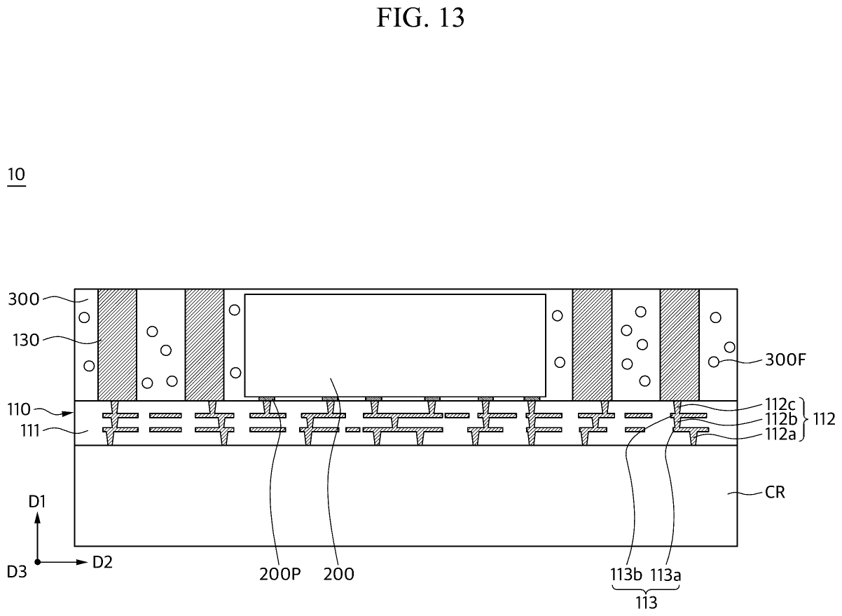

Referring to FIGS. 12 and 13, the method of manufacturing the semiconductor package 10 may include removing a portion of the molding film 300 to expose the post 130. The molding film 300, for example, may expose the post 130, to have a flat surface, through chemical mechanical polishing (CMP) using a grinder GR. Here, a portion of the molding film 300 may be removed to expose the post 130 while other part of the molding film 300 still remains on the semiconductor chip 200.

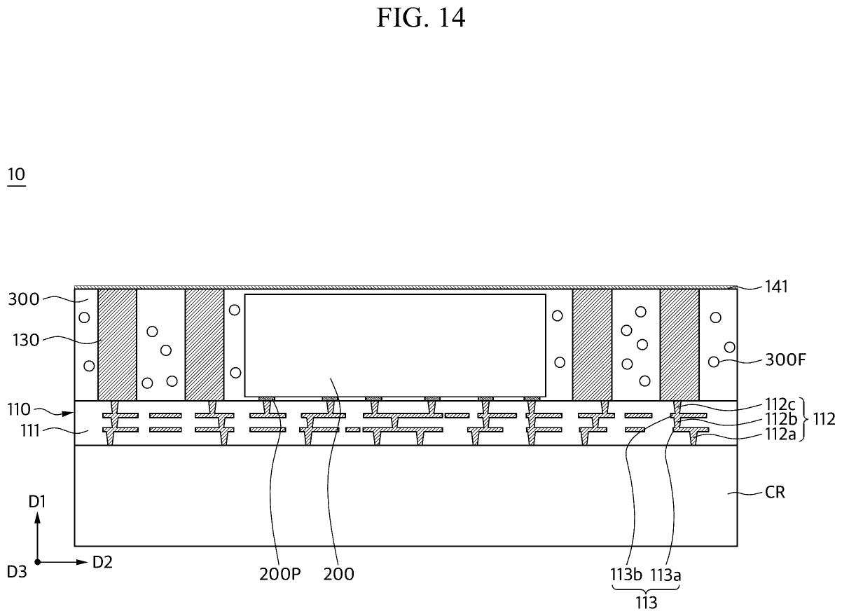

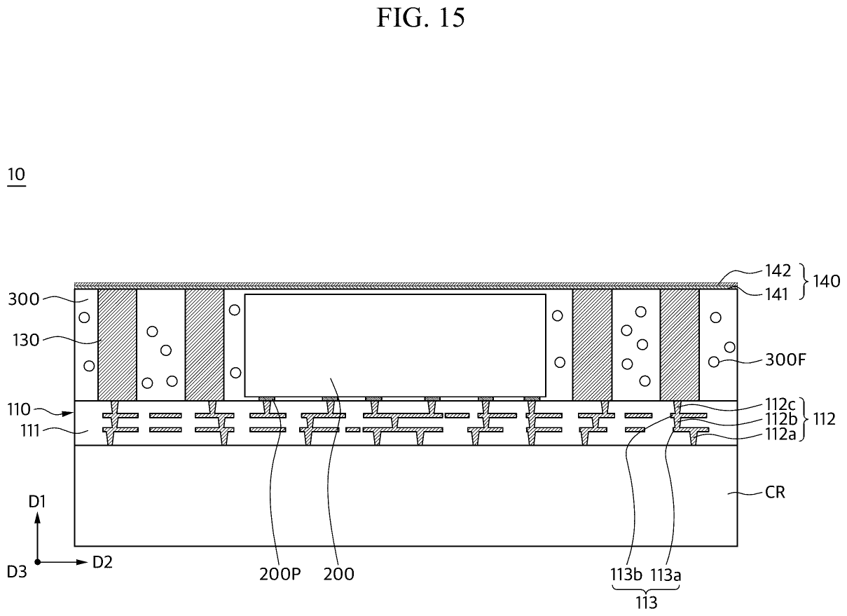

Referring to FIGS. 14 and 15, the method of manufacturing the semiconductor package 10 may include forming the barrier film 140 on the exposed post 130. The method of manufacturing the semiconductor package 10 may include forming the barrier film 140 on the exposed post 130 and flattened molding film 300. For example, the barrier film 140 may be formed through sputtering.

Referring to FIG. 14, the method of manufacturing the semiconductor package 10 may include forming the first barrier film 141 on the exposed post 130. The method of manufacturing the semiconductor package 10 may include forming the first barrier film 141 on the exposed post 130 and flattened molding film 300.

Referring to FIG. 15, the method of manufacturing the semiconductor package 10 may include forming the second barrier film 142 on the first barrier film 141. The method of manufacturing the semiconductor package 10 may include forming the second barrier film 142 so that the thickness of the second barrier film 142 is greater than the thickness of the first barrier film 141.

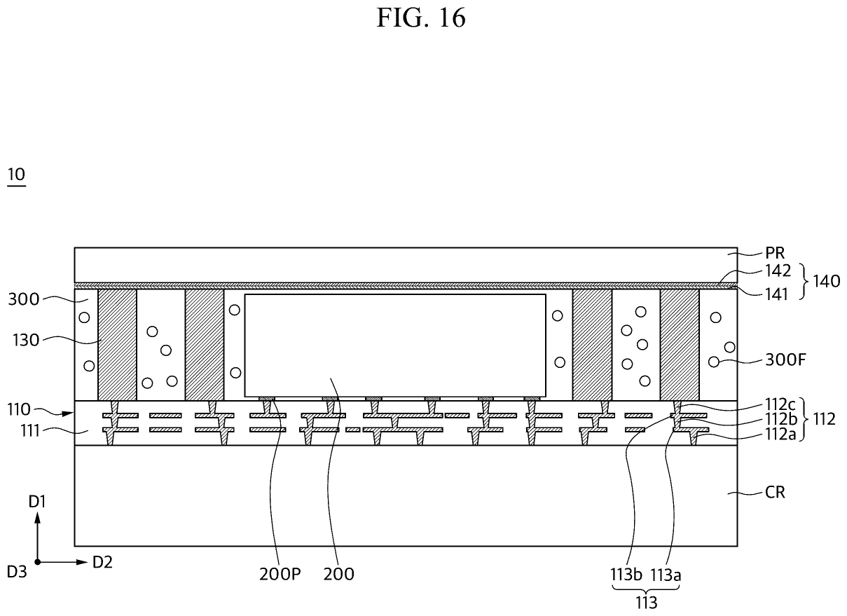

Referring to FIGS. 16 through 18, the method of manufacturing the semiconductor package 10 may include removing a portion of the barrier film 140 to re-expose the post 130.

Referring to FIG. 16, the method of manufacturing the semiconductor package 10 may include forming a photo resist PR on the barrier film 140. For example, the photo resist PR may be formed using the spin coating method. The photo resist PR, for example, may include organic polymer resin including a photosensitive material.

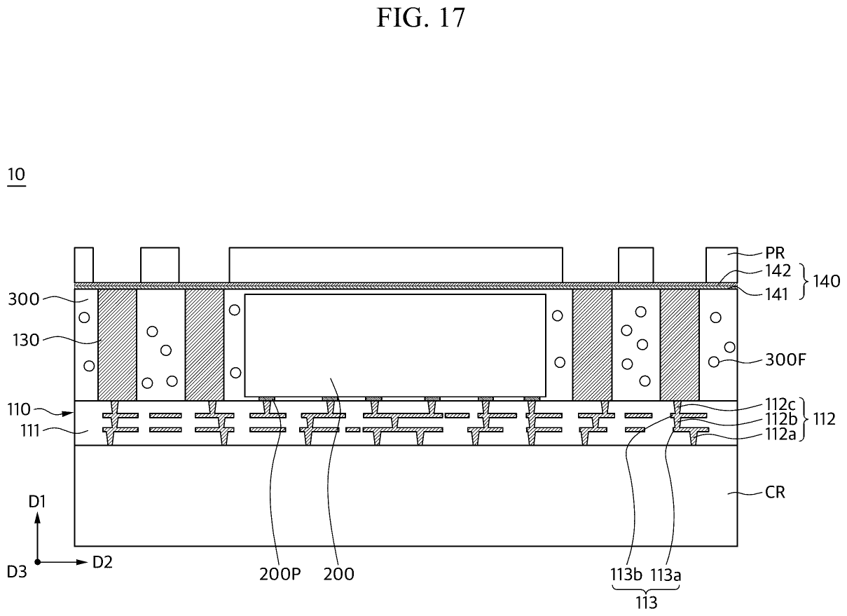

Referring to FIG. 17, the method of manufacturing the semiconductor package 10 may include forming a photo resist PR pattern through exposure and development. A photo resist pattern PF may be formed in a way that the barrier film 140 is exposed.

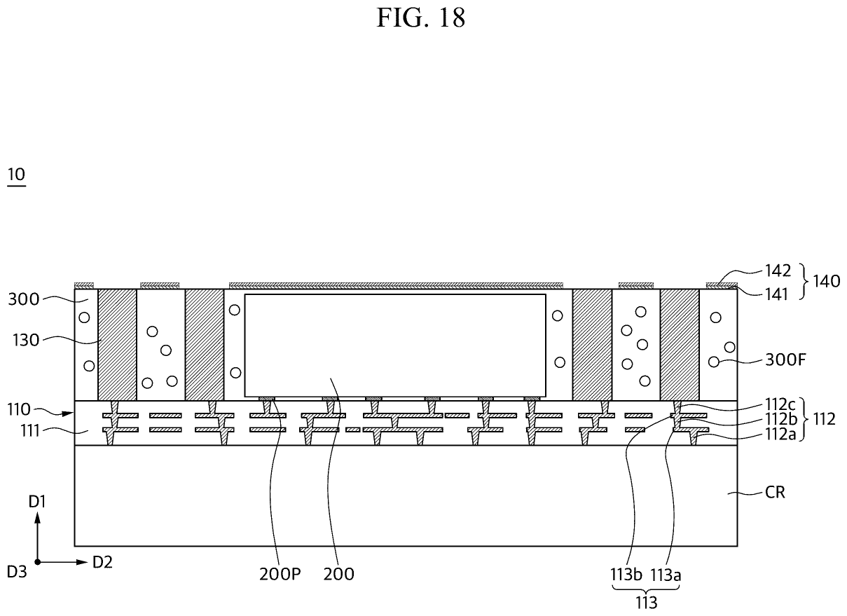

Referring to FIG. 18, the method of manufacturing the semiconductor package 10 may include etching the exposed barrier film 140 and removing the photo resist PR. A portion of the barrier film 140 may be etched to overlap the exposed area when viewed from the first direction D1, using the photo resist pattern PF as a mask. The post 130 may be re-exposed as a portion of the barrier film 140 is etched. The method of manufacturing the semiconductor package 10 may include removing the photo resist pattern PF through ashing.

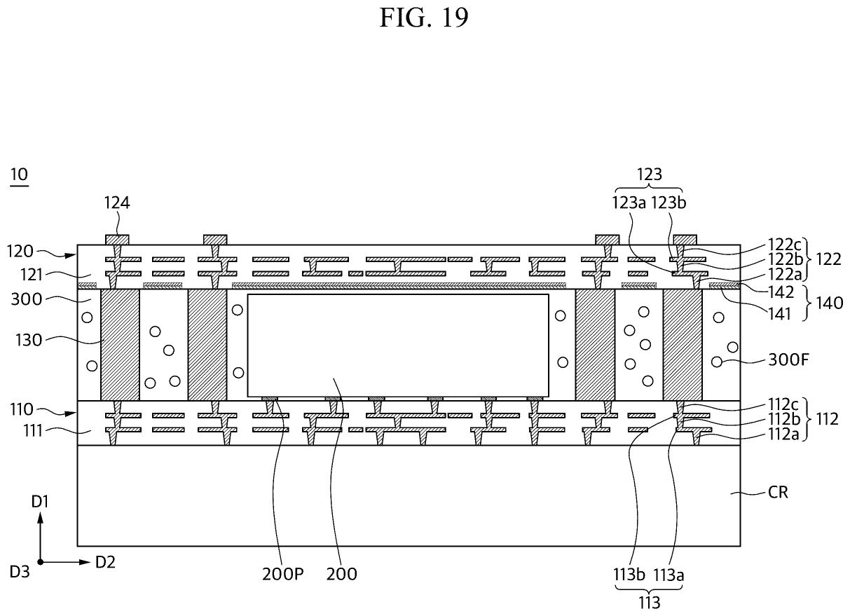

Referring to FIG. 19, the method of manufacturing the semiconductor package 10 may include forming the backside redistribution structure 120 on the molding film 300 so as to be electrically connected to the re-exposed post 130. Forming the backside redistribution structure 120 may reference the forming of the front redistribution structure 110 described above.

According to an example embodiment, the method of manufacturing the semiconductor package 10 may include forming the second insulating film 121 on the re-exposed post 130, barrier film 140, and molding film 300. The method of manufacturing the semiconductor package 10 may include forming via holes by selectively etching the second insulating film 121, and filling the via holes with a conductive material. The second interconnection structure including the backside redistribution via 122 and the backside redistribution line 123 may be formed by filling the via holes with a conductive material. For example, the method of manufacturing the semiconductor package 10 may include forming a first region which is a portion of the second insulating film 121, forming via holes by selectively etching them, and forming the backside redistribution via 122 by filling the via holes with a conductive material. The method of manufacturing the semiconductor package 10 may include forming a second region which is a portion of the second insulating film 121 in the first region in which the backside redistribution via 122 is formed, forming via holes by selectively etching them, and filling the via holes with a conductive material to form the backside redistribution line 123. By repeating the process, the backside redistribution via 122 including the first backside redistribution via 122a, the second backside redistribution via 122b and the third backside redistribution via 122c, and the backside redistribution line 123 including the first backside redistribution line 123a and the second backside redistribution line 123b may be formed. The backside redistribution via 122 and the backside redistribution line 123 may be formed through sputtering. The method of manufacturing the semiconductor package 10 may include forming the connection member 124 so as to be electrically connected to the second interconnection structure.

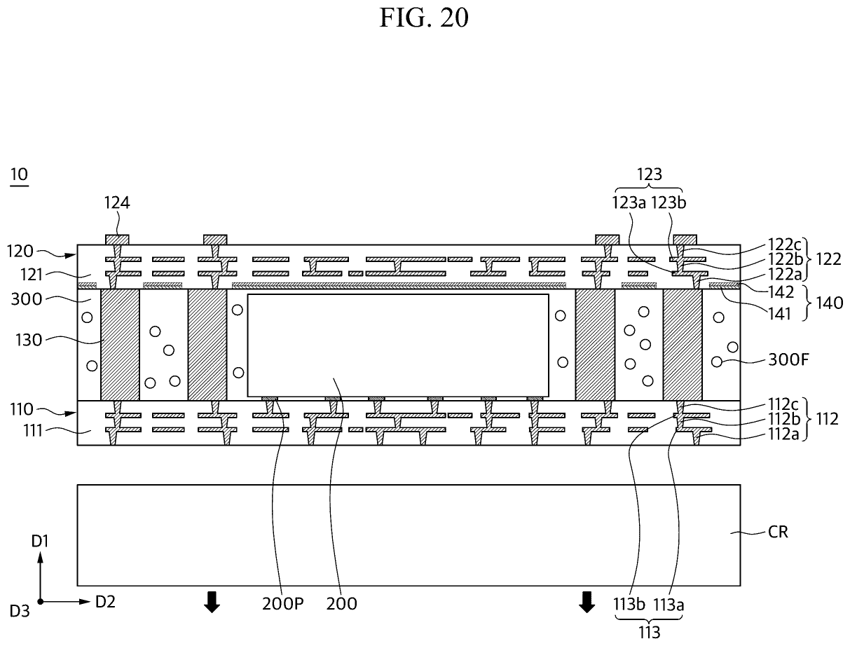

Referring to FIG. 20, the method of manufacturing the semiconductor package 10 may include removing the carrier CR after forming the backside redistribution structure 120. Then, the method of manufacturing the semiconductor package 10 may form the external connection structure 150 in an area at which the carrier CR is removed. The method of manufacturing the semiconductor package 10 may include forming the external connection insulating film 151 in an area at which the carrier CR is removed from the first insulating film 111, and forming the external connection pad 152 and external connection member 153 by referencing the method of forming the front redistribution structure 110 and the backside redistribution structure 120 described above.

FIGS. 8 through 11 and FIGS. 21 through 32 are example drawings for describing a method of manufacturing the semiconductor package 10 according to FIGS. 4 through 7.

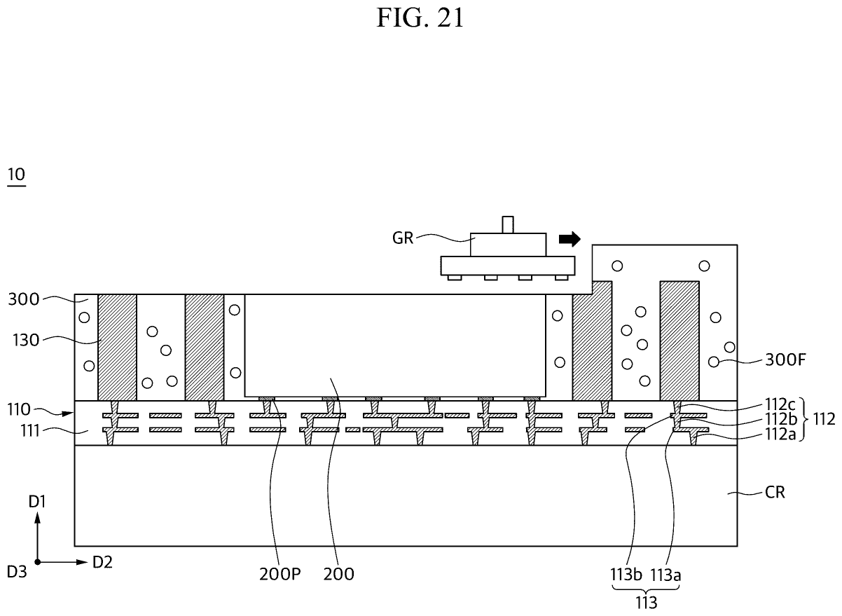

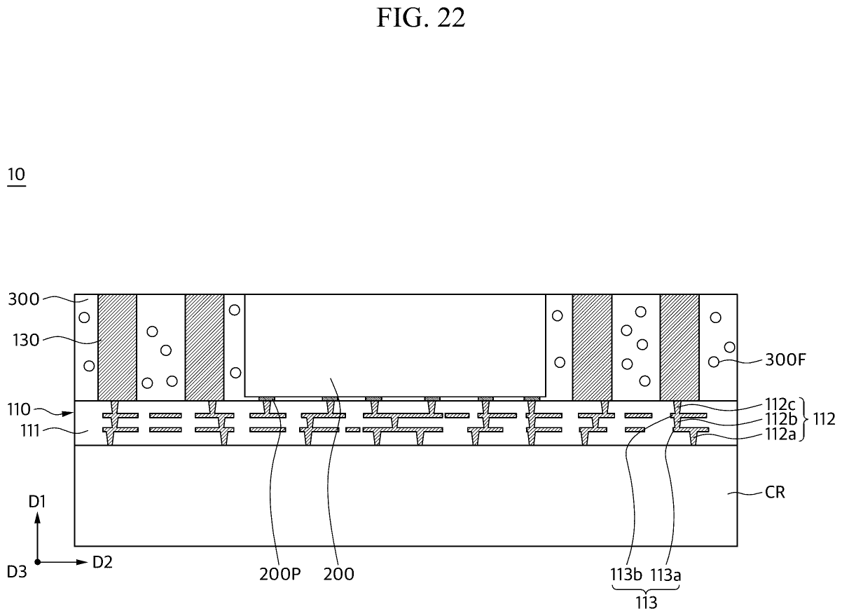

FIGS. 21 and 22 may be drawings illustrating processes following the process illustrated in FIG. 11, and descriptions of FIGS. 12 and 13 may be referenced unless otherwise contradicted. Referring to FIGS. 21 and 22, the method of manufacturing the semiconductor package 10 may include removing a portion of the molding film 300 to exposure the post 130 and semiconductor chip 200.

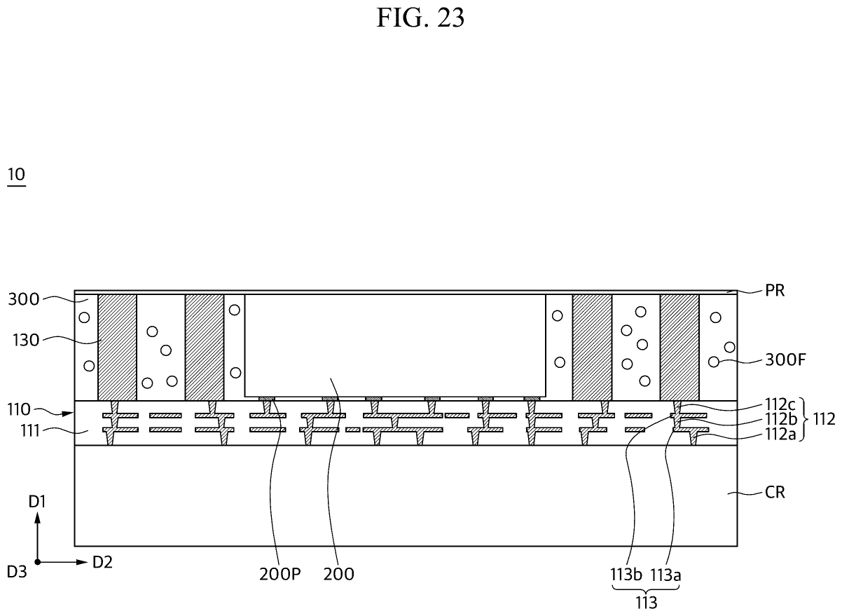

Referring to FIG. 23, the method of manufacturing the semiconductor package 10 may include forming the photo resist PR on the exposed post 130 and semiconductor chip 200. For example, the photo resist PR may be formed using the spin coating method. The photo resist PR may, for example, include organic polymer resin including a photosensitive material.

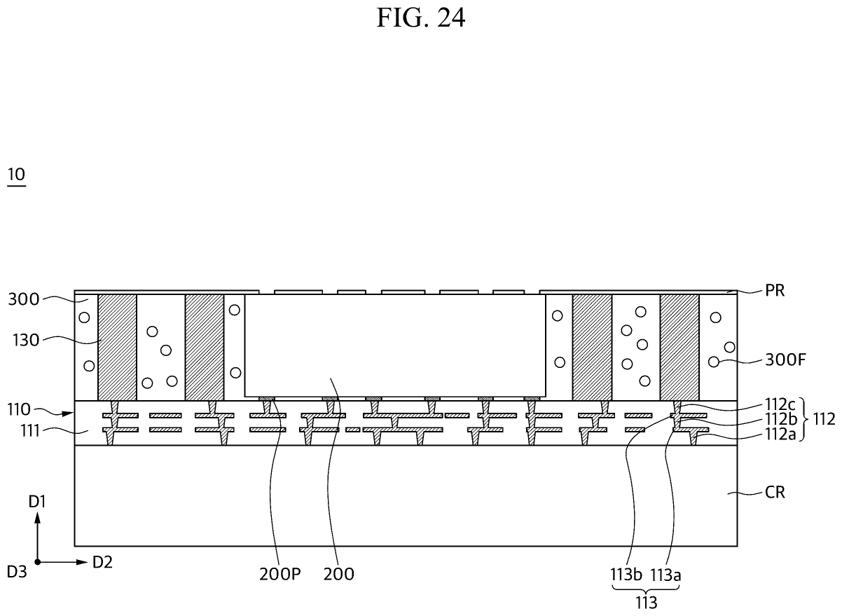

Referring to FIG. 24, the method of manufacturing the semiconductor package 10 may form the photo resist PR pattern through exposure and development, and the photo resist PR pattern may be formed to re-expose a portion of the semiconductor chip 200. Here, the re-exposed area may be an area in which a wiring of the semiconductor chip 200 is formed.

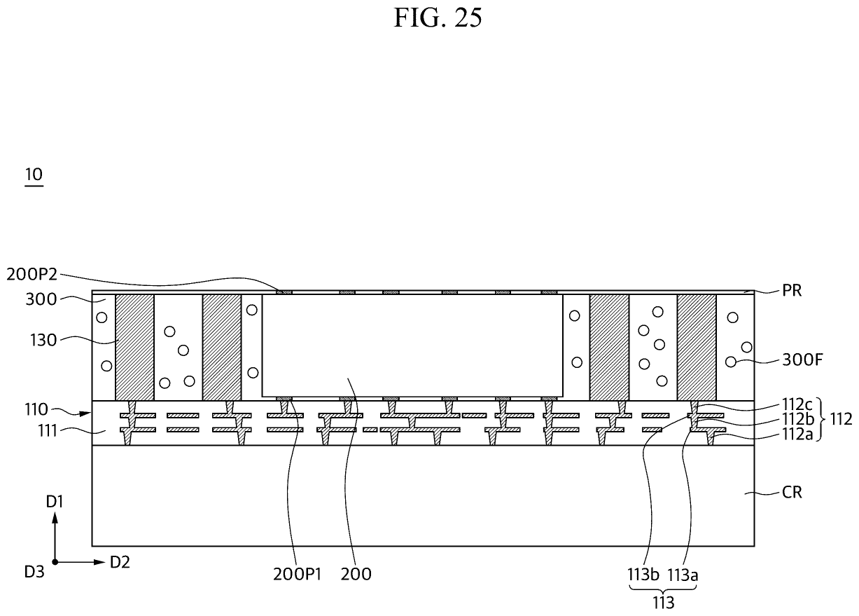

Referring to FIG. 25, the method of manufacturing the semiconductor package 10 may include forming the second chip pad 200P2 by filling the photo resist PR pattern with a conductive material. Here, the chip pad 200P of FIGS. 21 through 24 may be the first chip pad 200P1.

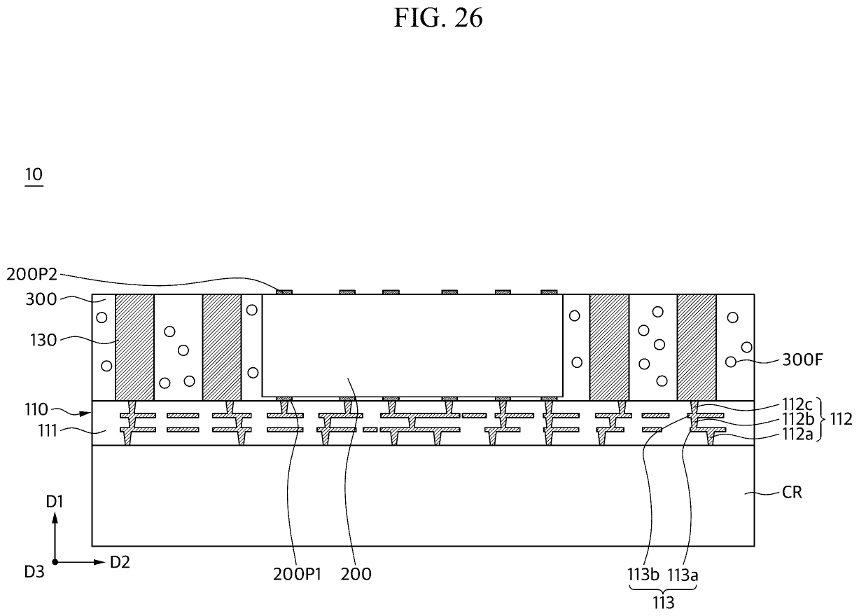

Referring to FIG. 26, with respect to the method of manufacturing the semiconductor package 10, the second chip pad 200P2 may be protruded from the semiconductor chip 200 toward the positive first direction +D1 by removing the photo resist PR.

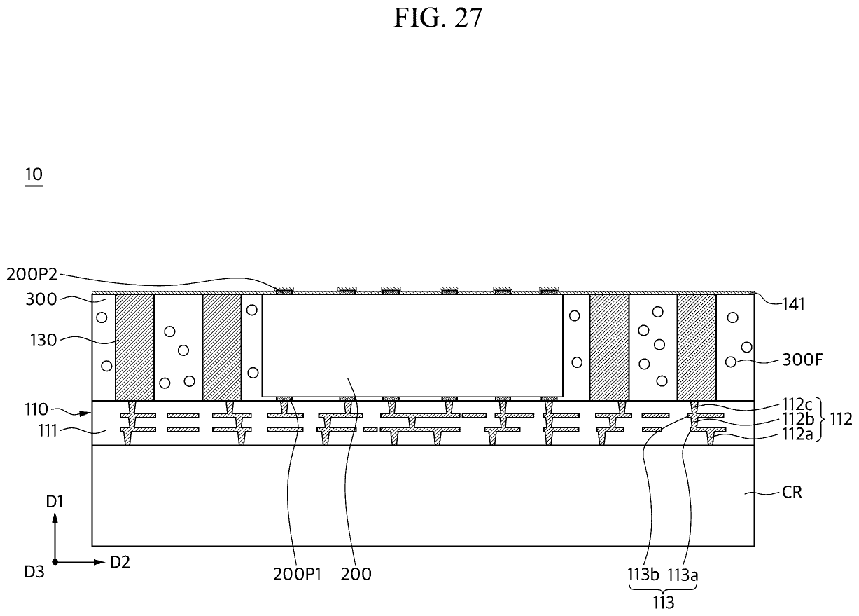

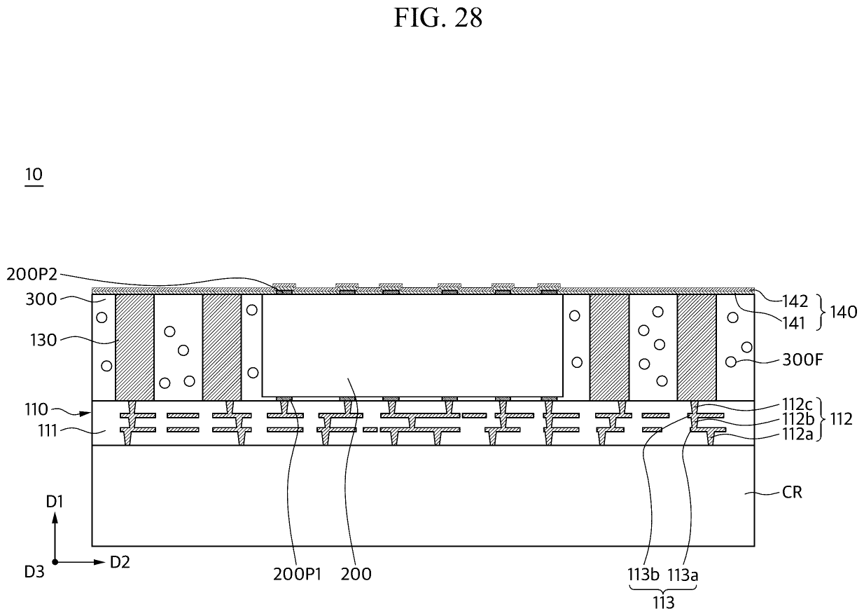

Referring to FIGS. 27 and 28, the method of manufacturing the semiconductor package 10 may include forming the barrier film 140 on the exposed post 130 and second chip pad 200P2. The method of manufacturing the semiconductor package 10 may include forming the barrier film 140 on the exposed post 130, second chip pad 200P2, and flattened molding film 300. For example, the barrier film 140 may be formed through sputtering.

Referring to FIG. 27, the method of manufacturing the semiconductor package 10 may include forming the first barrier film 141 on the exposed post 130 and second chip pad 200P2. The method of manufacturing the semiconductor package 10 may include forming the first barrier film 141 on the exposed post 130, second chip pad 200P2, and flattened molding film 300. The first barrier film 141 may be formed along a profile of an area where the second chip pad 200P2 is protruded, to surround the protruded area of the second chip pad 200P2.

Referring to FIG. 28, the method of manufacturing the semiconductor package 10 may include forming the second barrier film 142 on the first barrier film 141. The method of manufacturing the semiconductor package 10 may include forming the second barrier film 142 so that the thickness of the second barrier film 142 is greater than the thickness of the first barrier film 141. The second barrier film 142 may be formed along a profile of the first barrier film 141.

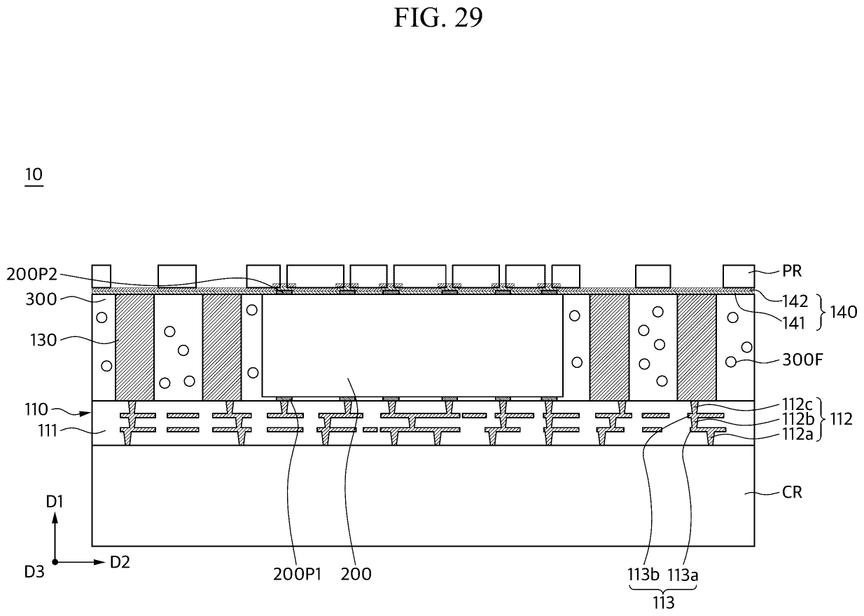

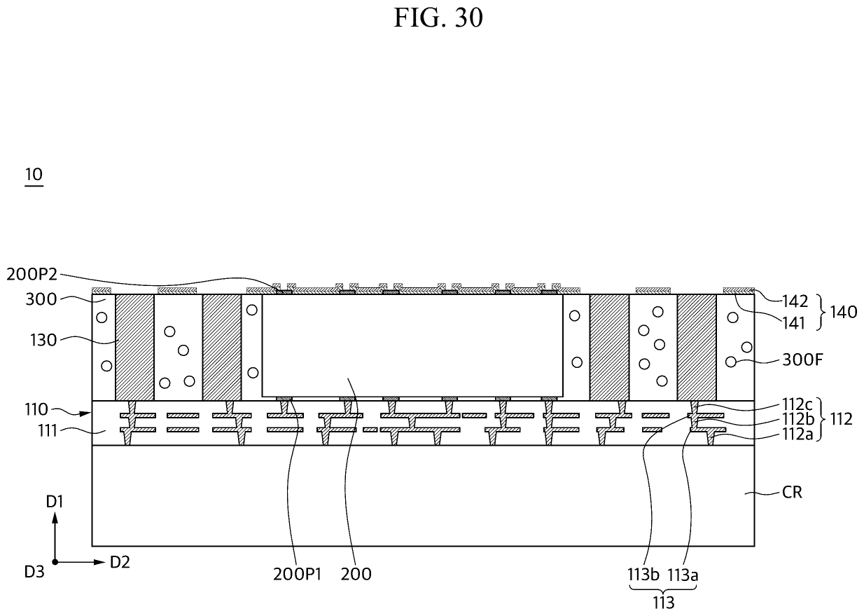

Referring to FIGS. 29 and 30, removing a portion of the barrier film 140 to re-expose the post 130 and second chip pad 200P2 may be included.

Referring to FIG. 29, the method of manufacturing the semiconductor package 10 may include forming the photo resist PR on the barrier film 140 and forming the photo resist PR pattern through exposure and development. The photo resist pattern PF may be formed in the way that the barrier film 140 and second chip pad 200P2 are exposed.

Referring to FIG. 30, the method of manufacturing the semiconductor package 10 may include etching the exposed barrier film 140 and removing the photo resist PR. A portion of the barrier film 140 may be etched to overlap the exposed area when viewed from the first direction D1, using the photo resist pattern PF as a mask. The post 130 and second chip pad 200P2 may be re-exposed as a portion of the barrier film 140 is etched. The method of manufacturing the semiconductor package 10 may include removing the photo resist pattern PF through ashing.

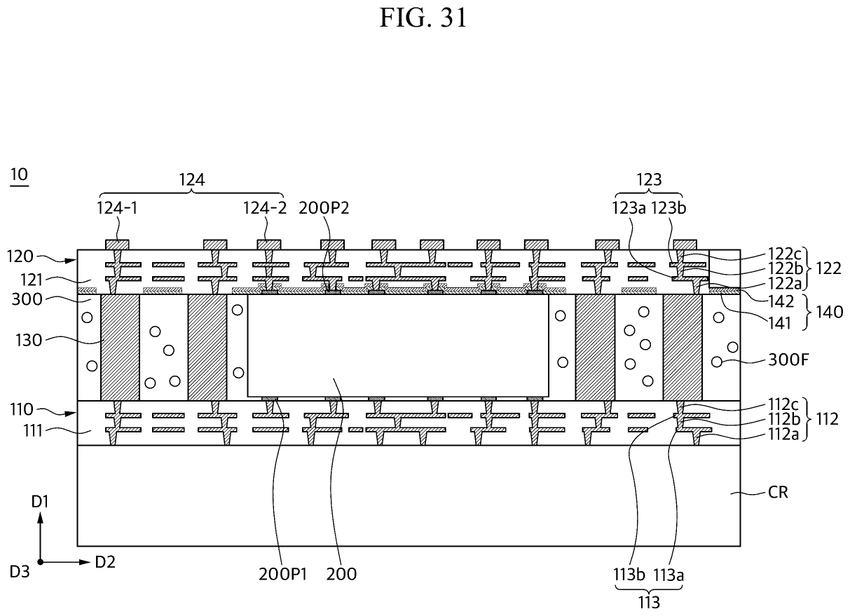

Referring to FIG. 31, the method of manufacturing the semiconductor package 10 may include forming the backside redistribution structure 120 on the molding film 300 so as to be electrically connected to the re-exposed post 130 and second chip pad 200P2. The description of FIG. 19 may be referenced in forming the backside redistribution structure 120 unless otherwise contradicted.

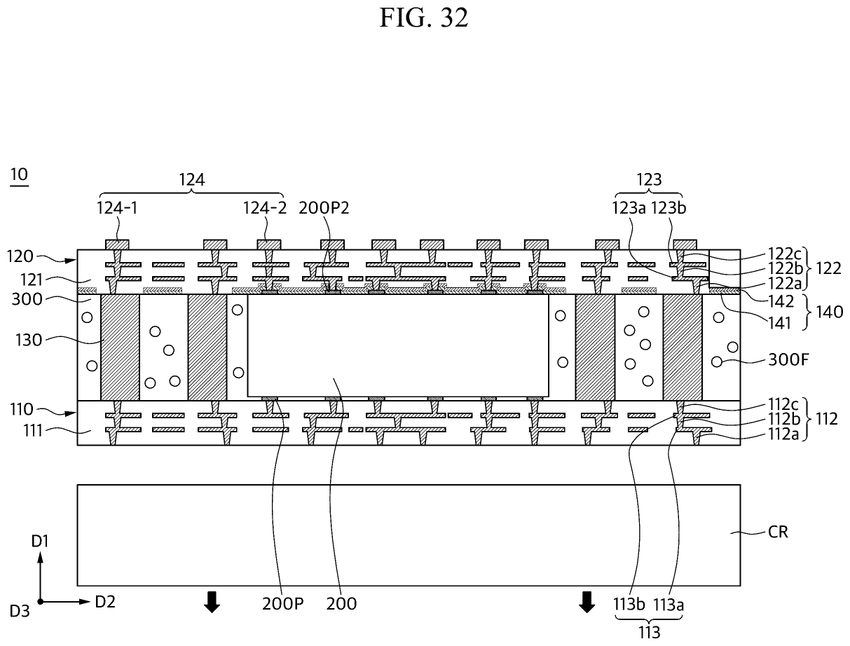

Referring to FIG. 32, the method of manufacturing the semiconductor package 10 may include removing the carrier CR after forming the backside redistribution structure 120. Then, the method of manufacturing the semiconductor package 10 may form the external connection structure 150 in an area at which the carrier CR is removed.

The example embodiments have been described with reference to the accompanying drawings above, however, the present disclosure is not limited to the above example embodiments and may be manufactured in various forms different from each other, and those skilled in the art to which the present disclosure belongs may understand that other embodiments may be implemented without changing the technical spirit or the required characteristics of the present disclosure. Therefore, in all aspects, the above-described example embodiments should be understood as mere examples and not as being limitative.

What is claimed is:

1. A semiconductor package comprising:
a front redistribution structure;
a semiconductor chip disposed above the front redistribution structure;
a post disposed on the front redistribution structure and extending in a first direction which is a direction substantially perpendicular to a surface of the front redistribution structure;
a molding film disposed on the front redistribution structure, surrounding at least a portion of the semiconductor chip and at least a portion of the post, the molding film including at least a portion disposed between the semiconductor chip and the front redistribution structure;
a barrier film disposed on the molding film and overlapping at least a portion of the molding film when viewed from the first direction; and
a backside redistribution structure disposed on the molding film.

2. The semiconductor package of claim 1, wherein the barrier film comprises a conductive material.

3. The semiconductor package of claim 1, wherein the barrier film includes:
a first barrier film disposed on the molding film, and
a second barrier film disposed on the first barrier film and further away from the front redistribution structure than the first barrier film.

4. The semiconductor package of claim 3, wherein a thickness of the first barrier film is smaller than a thickness of the second barrier film.

5. The semiconductor package of claim 4, wherein a ratio (T₁/T₂) of the thickness of the first barrier film (T₁) and the thickness of the second barrier film (T₂) is greater than or equal to 0.1 and less than 1.

6. The semiconductor package of claim 3, wherein the first barrier film comprises titanium (Ti).

7. The semiconductor package of claim 6, wherein the post and the second barrier film comprise identical materials.

8. The semiconductor package of claim 1, wherein the barrier film does not overlap the post when viewed from the first direction.

9. The semiconductor package of claim 8 wherein, when viewed from the first direction, the barrier film surrounds the post, and a portion of the molding film is disposed between the barrier film and the post.

10. The semiconductor package of claim 1, wherein the post passes through the molding film in the first direction.

11. The semiconductor package of claim 1, wherein the post is be spaced apart from the semiconductor chip in a second direction which is a direction substantially parallel to the surface of the front redistribution structure.

12. The semiconductor package of claim 11, wherein the post is in plurality, and
a plurality of the posts are spaced apart from each other in the second direction.

13. The semiconductor package of claim 1, wherein the front redistribution structure comprises:
a first insulating film;
a front redistribution via disposed within the first insulating film; and
a front redistribution line disposed within the first insulating film and electrically connected to the front redistribution via,
the backside redistribution structure comprises:
a second insulating film;
a backside redistribution via disposed within the second insulating film; and
a backside redistribution line disposed within the second insulating film and electrically connected to the backside redistribution via, and
each of the front redistribution structure and the backside redistribution structure is electrically connected to the post.

14. The semiconductor package of claim 13, wherein the second insulating film is in contact with the post, the barrier film, and the molding film.

15. The semiconductor package of claim 1, wherein a portion of the molding film is disposed between the semiconductor chip and the barrier film.

16. The semiconductor package of claim 1, wherein a length of the post in the first direction is substantially same as a length of the semiconductor chip in the first direction, or is greater than the length of the semiconductor chip.

17. A semiconductor package comprising:
a front redistribution structure;
a semiconductor chip disposed above the front redistribution structure;
a post disposed on the front redistribution structure and extending in a first direction which is a direction substantially perpendicular to a surface of the front redistribution structure;
a molding film disposed on the front redistribution structure, surrounding at least a portion of the semiconductor chip and at least a portion of the post, the molding film including at least a portion disposed between the semiconductor chip and the front redistribution structure;
a barrier film disposed on the molding film, and surrounding the post when viewed from the first direction; and
a backside redistribution structure disposed on the molding film.

18. The semiconductor package of claim 17, wherein a portion of the molding film is disposed between the barrier film and the post when viewed from the first direction.

19. The semiconductor package of claim 17, wherein the barrier film includes:
a first barrier film disposed on the molding film; and
a second barrier film disposed on the first barrier film and further away from the front redistribution structure than the first barrier film,
the first barrier film comprises titanium (Ti), and
the second barrier film comprises copper (Cu).

20. A semiconductor package comprising:
a front redistribution structure;
a semiconductor chip disposed above the front redistribution structure;
a post disposed on the front redistribution structure and extending in a first direction which is a direction substantially perpendicular to a surface of the front redistribution structure;
a molding film disposed on the front redistribution structure, surrounding at least a portion of the semiconductor chip and at least a portion of the post, the molding film including at least a portion disposed between the semiconductor chip and the front redistribution structure;
a barrier film disposed on the molding film and, when viewed from the first direction, overlapping at least a portion of the molding film, surrounding the post, and not overlapping the post; and
a backside redistribution structure disposed on the molding film,
wherein the barrier film includes:
a first barrier film disposed on the molding film; and
a second barrier film disposed on the first barrier film and further away from the front redistribution structure than the first barrier film,
a ratio (T₁/T₂) of a thickness of the first barrier film (T₁) and a thickness of the second barrier film (T₂) is greater than or equal to 0.1 and less than 1, and
a portion of the molding film is further disposed between the semiconductor chip and the barrier film.
